(19) United States
(12) Patent Application Publication
(10) Pub. No.: US 2026/0206222 A1
(43) Pub. Date: Jul. 16, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Eun Yeoung CHOI, Icheon-si Gyeonggi-do (KR); Young Jin NOH, Icheon-si Gyeonggi-do (KR); Dong Chul YOO, Icheon-si Gyeonggi-do (KR); Tae Hong GWON, Icheon-si Gyeonggi-do (KR); Ki Sun KIM, Icheon-si Gyeonggi-do (KR); Jong Gi KIM, Icheon-si Gyeonggi-do (KR); Jin Ho OH, Icheon-si Gyeonggi-do (KR)

(73) Assignee: SK hynix Inc., Icheon-si Gyeonggi-do (KR)

(21) Appl. No.: 19/208,308

(22) Filed: May 14, 2025

(30) Foreign Application Priority Data
Jan. 15, 2025 (KR) 10-2025-0006367

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor device includes a gate structure including insulating layers and conductive layers that are alternately stacked; a memory layer extending through the gate structure and including first convex portions protruding in different directions and first connection portions connecting the first convex portions to each other; an insulating core located in the memory layer; channel patterns located between the first convex portions and the insulating core, respectively; first protective patterns located between the channel patterns and the insulating core, respectively; and second protective patterns located between the first protective patterns and the insulating core, respectively.

### CROSS-REFERENCE TO RELATED APPLICATION

This present application claims priority under 35 U.S.C. § 119(a) to Korean Patent Application No. 10-2025-0006367 filed in the Korean Intellectual Property Office on Jan. 15, 2025, which application is incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including insulating layers and conductive layers that are alternately stacked; a memory layer extending through the gate structure and including first convex portions protruding in different directions and first connection portions connecting the first convex portions to each other; an insulating core located in the memory layer; channel patterns located between the first convex portions and the insulating core, respectively; first protective patterns located between the channel patterns and the insulating core, respectively; and second protective patterns located between the first protective patterns and the insulating core, respectively.

In an embodiment, a semiconductor device may include: a gate structure including insulating layers and conductive layers that are alternately stacked; an insulating core extending through the gate structure and including second convex portions protruding in different directions and a second connection portion connecting the second convex portions to each other; channel patterns located between the second convex portions and the gate structure, respectively; liner patterns located between the second convex portions and the channel patterns, respectively; first protective patterns located between the second convex portions and the liner patterns, respectively; and second protective patterns located between the second convex portions and the first protective patterns, respectively.

In an embodiment, a method of manufacturing a semiconductor device may include: forming a stack including first material layers and second material layers that are alternately stacked; forming a channel hole extending through the stack and having a clover shape protruding in different directions; forming a channel layer including convex portions protruding in different directions along a profile of the channel hole and connection portions connecting the convex portions to each other; forming first protective patterns on the convex portions, respectively; forming second protective patterns on the first protective patterns, respectively; and forming channel patterns by etching the connection portions using the first protective patterns and the second protective patterns as etching barriers.

### BRIEF DESCRIPTION OF THE DRAWINGS

FIGS. 1A and 1B are diagrams for describing a semiconductor device in accordance with an embodiment.

FIGS. 2A, 2B, 2C, and 2D are diagrams for describing a semiconductor device in accordance with an embodiment.

FIG. 3 is a diagram for describing a semiconductor device in accordance with an embodiment.

FIGS. 4A, 5A, 6A, 7A, 8A, and 9A and FIGS. 4B, 5B, 6B, 7B, 8B, and 9B are diagrams for describing a method of manufacturing a semiconductor device in accordance with an embodiment.

### DETAILED DESCRIPTION

Various embodiments are directed to a semiconductor device having a stable structure and improved characteristics and a method of manufacturing the semiconductor device.

According to the present technology, it is possible to provide a semiconductor device having a stable structure and improved reliability.

Hereafter, embodiments in accordance with the technical spirit of the present disclosure will be described with reference to the accompanying drawings.

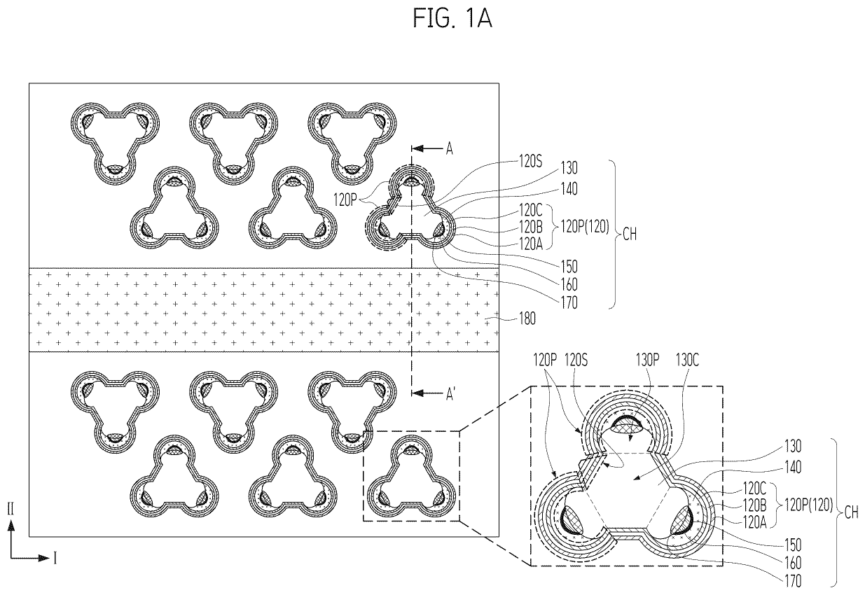

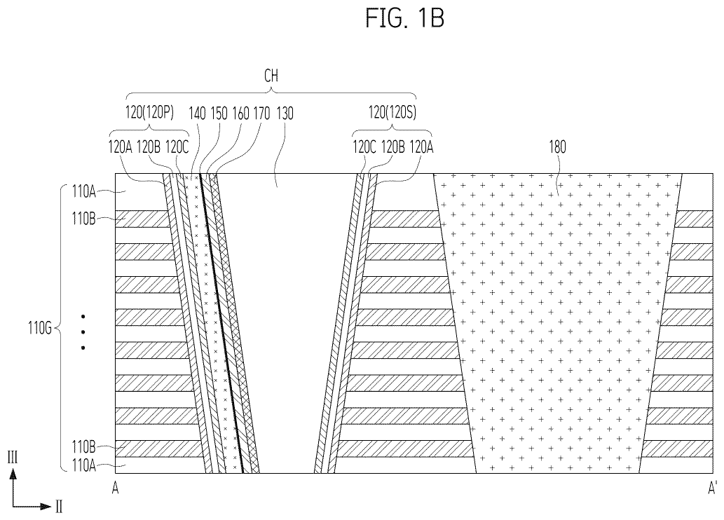

FIGS. 1A and 1B are diagrams for describing a semiconductor device in accordance with an embodiment. FIG. 1A is a plan view, and FIG. 1B is a cross-sectional view taken along line A-A′ of FIG. 1A.

Referring to FIGS. 1A and 1B, the semiconductor device may include a gate structure 110G, channel structures CH, and a slit structure 180.

The gate structure 110G may include insulating layers 110A and conductive layers 110B that are alternately stacked. The conductive layers 110B may be gate lines, such as a source select line, word lines, and a drain select line. A source select transistor, memory cells, or a drain select transistor may be located in regions in which the channel structures CH and the conductive layers 110B intersect each other. For example, at least one source select transistor, a plurality of memory cells, and at least one drain select transistor that are stacked along the channel structure CH may constitute one memory string. The conductive layers 110B may each include a conductive material, such as tungsten, molybdenum, or polysilicon. The insulating layers 110A may each include an insulating material, such as oxide.

The channel structures CH may extend through the gate structure 110G. The channel structures CH may each include a memory layer 120, an insulating core 130, channel patterns 140, first protective patterns 160, and second protective patterns 170. The channel structures CH may each further include liner patterns 150.

The memory layer 120 may extend through the gate structure 110G and may include first convex portions 120P protruding in different directions and first connection portions 120S connecting the first convex portions 120P to each other. For example, the memory layer 120 may have a clover shape. The memory layer 120 may include a blocking layer 120A, a data storage layer 120B, and a tunneling layer 120C. Here, the data storage layer 120B may be located between the blocking layer 120A and the tunneling layer 120C. The blocking layer 120A and the tunneling layer 120C may each include oxide. The data storage layer 120B may include a floating gate, a nitride layer, a variable resistance layer, or the like.

For reference, FIGS. 1A and 1B show the memory layer 120 includes three first convex portions 120P; however, the number of the first convex portions 120P is not limited thereto. For example, the memory layer 120 may include two or more first convex portions.

The insulating core 130 may extend through the gate structure 110G. The insulating core 130 may include second convex portions 130P corresponding to the first convex portions 120P and may include a second connection portion 130C corresponding to the first connection portions 120S. Here, the second connection portion 130C may connect the second convex portions 130P to each other. Referring to FIG. 1B, the insulating core 130 may be located in the memory layer 120. The insulating core 130 may include an insulating material, such as oxide.

The channel patterns 140 may extend through the gate structure 110G and may be located in the memory layer 120 as shown in FIG. 1B. The channel patterns 140 may be located between the memory layer 120 and the insulating core 130, respectively. For example, the channel patterns 140 may be located between the first convex portions 120P of the memory layer 120 and the insulating core 130, respectively. The channel patterns 140 may each include polysilicon or the like.

The liner patterns 150 may extend through the gate structure 110G and may be located to be adjacent to the channel patterns 140, respectively. For example, the liner patterns 150 may be located between the channel patterns 140 and the first protective patterns 160, respectively. The liner patterns 150 may each include an insulating material, such as oxide. The liner patterns 150 may each include silicon oxide. For example, the liner patterns 150 may include SiO₂.

The first protective patterns 160 may extend through the gate structure 110G and may be located to be adjacent to the liner patterns 150, respectively, so that the liner patterns 150 may be between the first protective patterns 160 and the channel patterns 140, respectively. For example, the first protective patterns 160 may be located between the channel patterns 140 and the insulating core 130, respectively. The first protective patterns 160 may include outer walls in contact with the liner patterns 150 and inner walls in contact with the second protective patterns 170. Here, a curvature of the outer walls of the first protective patterns 160 may be greater than a curvature of the inner walls of the first protective patterns 160. For example, the first protective patterns 160 may each have a crescent shape, each of the first protective patterns 160 having a thicker center region than an edge region.

The first protective patterns 160 may extend follow contours of portions of sidewalls of the channel patterns 140. The first protective patterns 160 may each include a different material compared to the liner patterns 150. For example, the first protective patterns 160 may each include an insulating material, such as nitride. The first protective patterns 160 may each include silicon nitride. For example, the first protective patterns 160 may each include Si₃N₄.

The second protective patterns 170 may extend through the gate structure 110G and may be located to be adjacent to the first protective patterns 160, respectively, so that first protective patterns 160 may be between the second protective patterns 170 and the liner patterns 150, respectively. For example, the second protective patterns 170 may be located between the first protective patterns 160 and the insulating core 130, respectively. The second protective patterns 170 may each have a different shape compared to the liner patterns 150 and the first protective patterns 160. For example, the second protective patterns 170 may each have an elliptical shape.

The second protective patterns 170 may each include a different material compared to the first protective patterns 160. For example, the second protective patterns 170 may each include an insulating material, such as oxide. The second protective patterns 170 may each include silicon oxide. As an example, the second protective patterns 170 may each include SiO₂. As another example, the second protective patterns 170 may each include SiOC. There may be boundary surfaces between the second protective patterns 170 and the insulating core 130. However, the present disclosure is not limited thereto, and there might not be boundary surfaces between the second protective patterns 170 and the insulating core 130.

According to an embodiment of the present disclosure, the liner patterns 150, the first protective patterns 160, and the second protective patterns 170 may be located between the channel patterns 140 and the insulating core 130. The liner patterns 150, the first protective patterns 160, and the second protective patterns 170 may prevent the channel patterns 140 from being damaged.

The slit structure 180 may extend through the gate structure 110G. The slit structure 130 may include at least one of an insulating material, a semiconductor material, or a conductive material.

According to the structure described above, the channel structure CH may include the memory layer 120 and the insulating core 130, each having a clover shape including the first convex portions 120P and the second convex portions 130P protruding in different directions. The channel patterns 140 may be located between the first convex portions 120P and the second convex portions 130P, respectively. In such a case, a plurality of memory strings may be configured in one channel structure CH, and thus, the degree of integration of the semiconductor device may be improved.

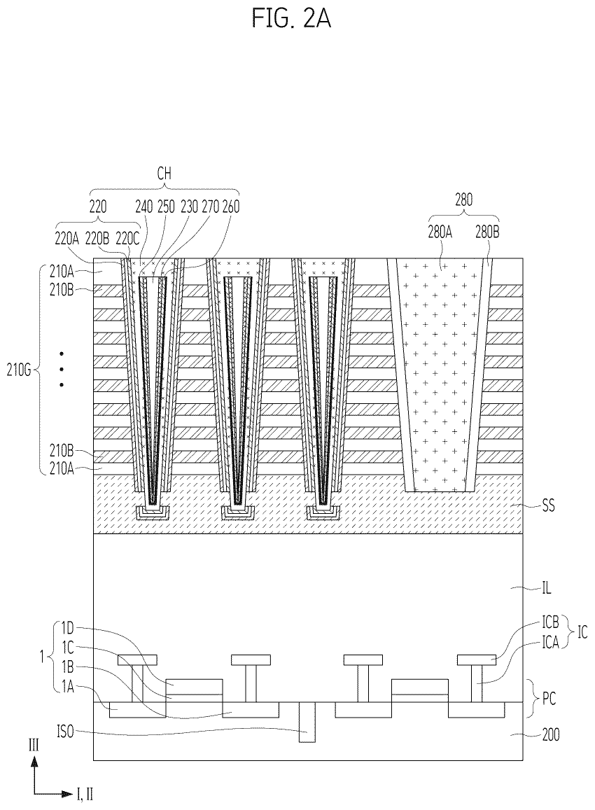

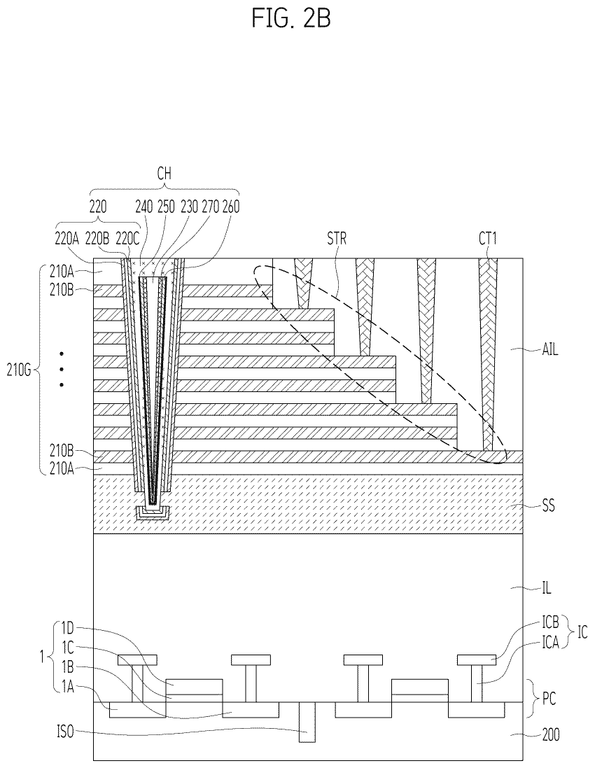

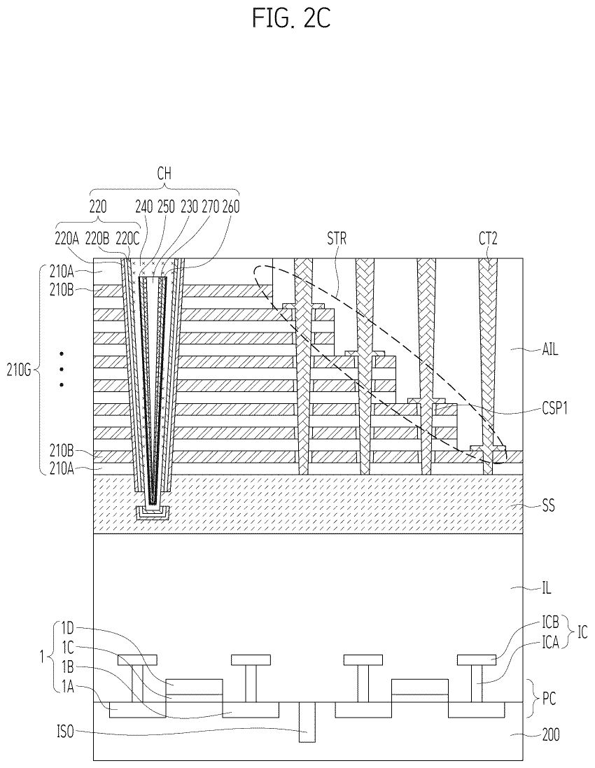

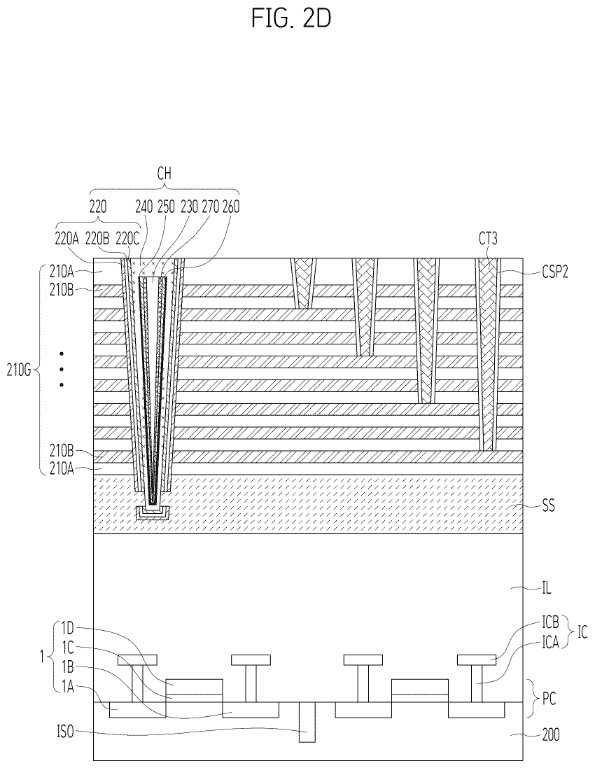

FIGS. 2A, 2B, 2C, and 2D are diagrams for describing a semiconductor device in accordance with an embodiment. Hereinafter, the content overlapping with the previously described content will be omitted.

Referring to FIGS. 2A, 2B, 2C, and 2D, the semiconductor device may include a substrate 200, a peripheral circuit PC, an element isolation layer ISO, an interconnection structure IC, an interlayer insulating layer IL, a source structure SS, a gate structure 210G, channel structures CH, and a slit structure 280. The semiconductor device may further include contact vias CT1, CT2, and CT3, contact spacers CSP1 and CSP2, and an additional interlayer insulating layer AIL.

The peripheral circuit PC may be located on the substrate 200. The peripheral circuit PC may include a transistor 1, a capacitor, and the like. The transistor 1 may include junctions 1A and 1B, a gate electrode 1D, and a gate insulating layer 1C. Here, the gate insulating layer 1C may be located between the gate electrode 1D and the substrate 200. The element isolation layer ISO may be located in the substrate 200, an active region may be defined by the element isolation layer ISO, and the transistor 1 may be located in the active region.

The interconnection structure IC may be located on the peripheral circuit PC. The interconnection structure IC may be located in the interlayer insulating layer IL. Here, the interlayer insulating layer IL may be located on the substrate 200. The interconnection structure IC may include vias ICA and wiring lines ICB.

The interconnection structure IC may be connected to the peripheral circuit PC. For example, at least one of the vias ICA may be connected to the transistor 1. At least one of the vias ICA may connect the wiring lines ICB to each other. The wiring lines ICB may connect the vias ICA to each other. The interconnection structure IC may include a conductive material, such as tungsten. The interlayer insulating layer IL may include an insulating material, such as oxide.

The gate structure 210G may be located on the source structure SS. Here, the source structure SS may be located between the peripheral circuit PC and the gate structure 210G. The gate structure 210G may include insulating layers 210A and conductive layers 210B that are alternately stacked.

The channel structures CH may extend into the source structure SS through the gate structure 210G. The channel structures CH may each include a memory layer 220, an insulating core 230 located in the memory layer 220, and channel patterns 240 located between the memory layer 220 and the insulating core 230. The memory layer 220 may include a blocking layer 220A, a data storage layer 220B, and a tunneling layer 220C. The channel patterns 240 may be connected to the source structure SS.

In addition, the channel structures CH may further include liner patterns 250, first protective patterns 260, and second protective patterns 270 located between the channel patterns 240 and the insulating core 230.

The memory layer 220, the insulating core 230, the channel patterns 240, the liner patterns 250, the first protective patterns 260, and the second protective patterns 270 may correspond to the memory layer 120, the insulating core 130, the channel patterns 140, the liner patterns 150, the first protective patterns 160, and the second protective patterns 170 of FIGS. 1A and 1B, respectively.

The slit structure 280 may extend into the source structure SS through the gate structure 210G. The slit structure 280 may include a source contact structure 280A and an insulating spacer 280B surrounding the source contact structure 280A. Here, the source contact structure 280A may be connected to the source structure SS. The insulating spacer 280B may insulate the source contact structure 280A and the conductive layers 210B from each other.

Referring to FIGS. 2B and 2C, the gate structure 210G may include a staircase structure STR. The additional interlayer insulating layer AIL may be located on the staircase structure STR of the gate structure 210G. An upper surface of at least one of the conductive layers 210B of the gate structure 210G may be in contact with the additional interlayer insulating layer AIL. The additional interlayer insulating layer AIL may include an insulating material, such as oxide.

Referring to FIG. 2B again, the contact vias CT1 may extend through the additional interlayer insulating layer AIL. Each of the contact vias CT1 may be connected to one of the conductive layers 210B of the gate structure 210G. Here, the contact vias CT1 may have different heights. The contact vias CT1 may each include a conductive material, such as tungsten.

Referring to FIG. 2C again, the contact vias CT2 may extend through the additional interlayer insulating layer AIL and the gate structure 210G. Each of the contact vias CT2 may be connected to one of the conductive layers 210B of the gate structure 210G. For example, each of the contact vias CT2 may include a body portion and a protrusion portion protruding from the body portion and may be connected to one of the conductive layers 210B through the protrusion portion. Here, the protrusion portions of the contact vias CT2 may be connected to upper surfaces of the conductive layers 210B, respectively. The contact vias CT2 may have substantially the same height. The contact vias CT2 may each include a conductive material, such as tungsten.

The contact spacers CSP1 may be located at levels corresponding to the conductive layers 210B. The contact spacers CSP1 may prevent the conductive layers 210B and the body portions of the contact vias CT2 from being electrically connected to each other. Here, the contact spacers CSP1 may each include an insulating material, such as oxide.

Referring to FIG. 2D, the gate structure 210G might not include the staircase structure STR. The contact vias CT3 may extend through the gate structure 210G. Each of the contact vias CT3 may be connected to one of the conductive layers 210B of the gate structure 210G. The contact spacers CSP2 may surround sidewalls of the contact vias CT3, respectively. The contact spacers CSP2 may prevent the remaining conductive layers 210B, excluding the conductive layer 210B connected to the contact via CT3, from being electrically connected to the contact vias CT3. The contact vias CT3 may have different heights. The contact vias CT3 may each include a conductive material, such as tungsten, and the contact spacers CSP2 may each include an insulating material, such as oxide.

According to the structure described above, the source structure SS may be located on the peripheral circuit PC, and the gate structure 210G may be located on the source structure SS. The channel structures CH may extend into the source structure SS through the gate structure 210G, and the channel patterns 240 of the channel structures CH may be connected to the source structure SS. The slit structure 280 may extend into the source structure SS through the gate structure 210G, and the source contact structure 280A of the slit structure 280 may be connected to the source structure SS.

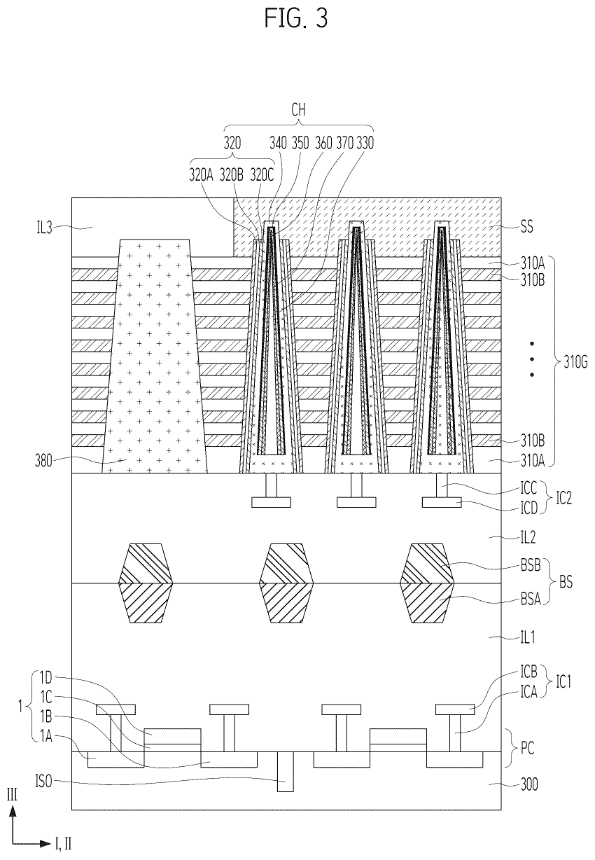

FIG. 3 is a diagram for describing a semiconductor device in accordance with an embodiment. Hereinafter, the content overlapping with the previously described content will be omitted.

Referring to FIG. 3, the semiconductor device may include a substrate 300, a peripheral circuit PC, a source structure SS, a bonding structure BS, a gate structure 310G, channel structures CH, a slit structure 380, an element isolation layer ISO, a first interconnection structure IC1, a second interconnection structure IC2, a first interlayer insulating layer IL1, a second interlayer insulating layer IL2, and a third interlayer insulating layer IL3.

The peripheral circuit PC may be located on the substrate 300. The peripheral circuit PC may include a transistor 1. The transistor 1 may include junctions 1A and 1B, a gate electrode 1D, and a gate insulating layer 1C. The element isolation layer ISO may be located in the substrate 300, an active region may be defined by the element isolation layer ISO, and the transistor 1 may be located in the active region.

The first interconnection structure IC1 may be located on the peripheral circuit PC. The first interconnection structure IC1 may be located in the first interlayer insulating layer IL1. Here, the first interlayer insulating layer IL1 may be located on the substrate 300. The first interconnection structure IC1 may include first vias ICA and first wiring lines ICB. The first interconnection structure IC1 may include a conductive material, such as tungsten. The first interlayer insulating layer IL1 may include an insulating material, such as oxide or nitride.

The bonding structure BS may be located on the peripheral circuit PC. For example, the bonding structure BS may be located on the first interconnection structure IC1. The bonding structure BS may include first bonding pads BSA and second bonding pads BSB. The first bonding pads BSA may be located in the first interlayer insulating layer IL1. The second bonding pads BSB may be located on the first bonding pads BSA and may be located in the second interlayer insulating layer IL2. Here, the second interlayer insulating layer IL2 may be located on the first interlayer insulating layer IL1. The bonding structure BS may include a conductive material, such as copper. The second interlayer insulating layer IL2 may include an insulating material, such as oxide or nitride.

The second interconnection structure IC2 may be located over the bonding structure BS. The second interconnection structure IC2 may be located in the second interlayer insulating layer IL2. The second interconnection structure IC2 may include second vias ICC and second wiring lines ICD. Although not illustrated in FIG. 3, the second interconnection structure IC2 may be connected to the bonding structure BS. The second interconnection structure IC2 may include a conductive material, such as tungsten.

The gate structure 310G may include insulating layers 310A and conductive layers 310B that are alternately stacked. The channel structures CH may extend into the source structure SS through the gate structure 310G. Here, the source structure SS may be located on the gate structure 310G. The channel structures CH may each include a memory layer 320, an insulating core 330 located in the memory layer 320, and channel patterns 340 located between the memory layer 320 and the insulating core 330. The memory layer 320 may include a blocking layer 320A, a data storage layer 320B, and a tunneling layer 320C. The channel patterns 340 may be connected to the source structure SS.

In addition, the channel structures CH may further include liner patterns 350, first protective patterns 360, and second protective patterns 370 located between the channel patterns 340 and the insulating core 330.

The memory layer 320, the insulating core 330, the channel patterns 340, the liner patterns 350, the first protective patterns 360, and the second protective patterns 370 may correspond to the memory layer 120, the insulating core 130, the channel patterns 140, the liner patterns 150, the first protective patterns 160, and the second protective patterns 170 of FIGS. 1A and 1B, respectively.

The slit structure 380 may extend into the third interlayer insulating layer IL3 through the gate structure 310G. The third interlayer insulating layer IL3 may be located on the gate structure 310G and may be located at a level corresponding to the source structure SS. The slit structure 380 may include an insulating material, a conductive material, a semiconductor material, or the like. The third interlayer insulating layer IL3 may include an insulating material, such as oxide.

According to the structure described above, the semiconductor device may include the bonding structure BS. The bonding structure BS may be located on the peripheral circuit PC, and the source structure SS may be located on the bonding structure BS. The bonding structure BS may be electrically connected to the peripheral circuit PC.

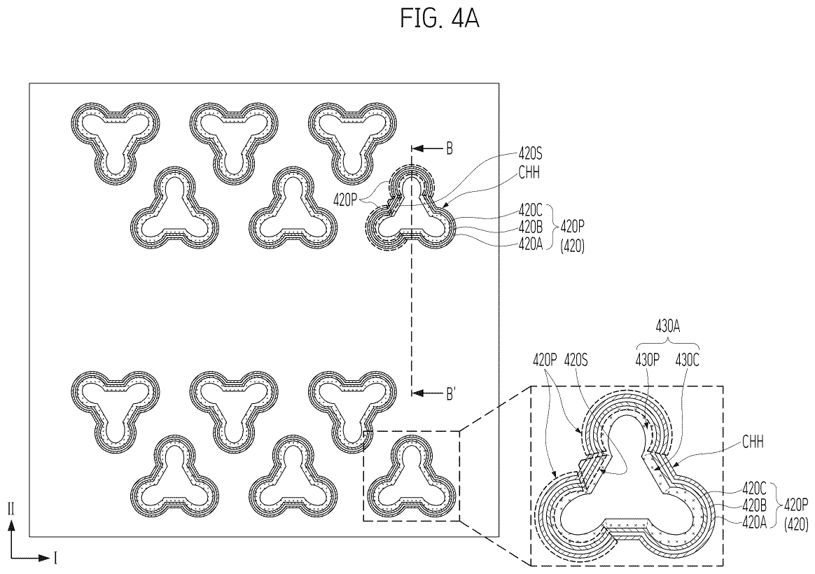

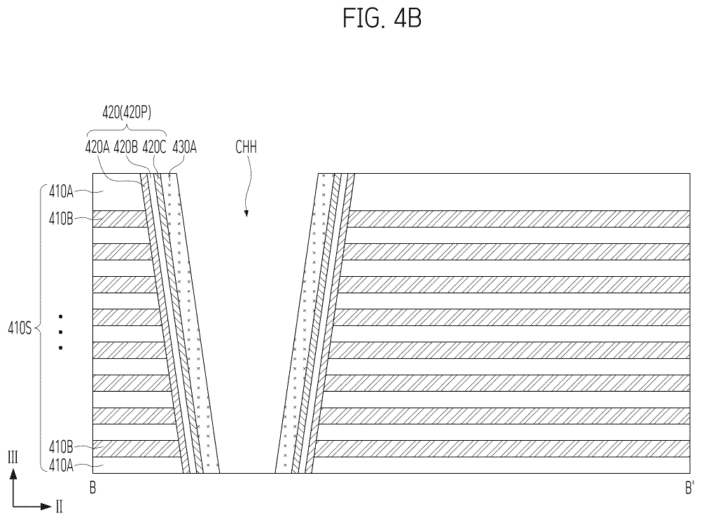

FIGS. 4A, 5A, 6A, 7A, 8A, and 9A and FIGS. 4B, 5B, 6B, 7B, 8B, and 9B are diagrams for describing a method of manufacturing a semiconductor device in accordance with an embodiment. FIGS. 4A, 5A, 6A, 7A, 8A, and 9A are plan views, and FIGS. 4B, 5B, 6B, 7B, 8B, and 9B are cross-sectional views taken along lines B-B′ of FIGS. 4A, 5A, 6A, 7A, 8A, and 9A, respectively. Hereinafter, the content overlapping with the previously described content will be omitted.

Referring to FIGS. 4A and 4B, a stack 410S may be formed by alternately stacking first material layers 410A and second material layers 410B. Here, the first material layers 410A may each include an insulating material, such as oxide, and the second material layers 410B may each include a sacrificial material, such as nitride. Alternatively, the first material layers 410A may each include an insulating material, such as oxide, and the second material layers 410B may each include a conductive material, such as tungsten, molybdenum, or polysilicon.

Subsequently, channel holes CHH extending through the stack 410S may be formed. For example, channel holes CHH having a clover shape in different directions may be formed. Here, the clover shape may refer to a shape in which a plurality of holes each having a circular shape or an elliptical shape are connected to each other.

Subsequently, memory layers 420 may be formed in the channel holes CHH, respectively, along profiles of the channel holes CHH. For example, the memory layer 420 may be formed by sequentially forming a blocking layer 420A, a data storage layer 420B, and a tunneling layer 420C in the channel hole CHH. The memory layer 420 may include first convex portions 420P and first connection portions 420S connecting the first convex portions 420P to each other. Here, the first convex portions 420P may protrude in different directions, and the first connection portions 420S may be flat. However, the present disclosure is not limited thereto, and the first connection portions 420S may each include a curved surface. The blocking layer 420A and the tunneling layer 420C may each include oxide. The data storage layer 420B may include at least one of a floating gate, a nitride layer, or a variable resistance layer.

Subsequently, a channel layer 430A may be formed along the profile of the memory layer 420. For example, the channel layer 430A including second convex portions 430P protruding in different directions and second connection portions 430C connecting the second convex portions 430P to each other may be formed along the profile of the memory layer 420. In such a case, the second convex portions 430P may be formed at locations corresponding to the first convex portions 420P, and the second connection portions 430C may be formed at locations corresponding to the first connection portions 420S. Here, the channel layer 430A may include polysilicon or the like.

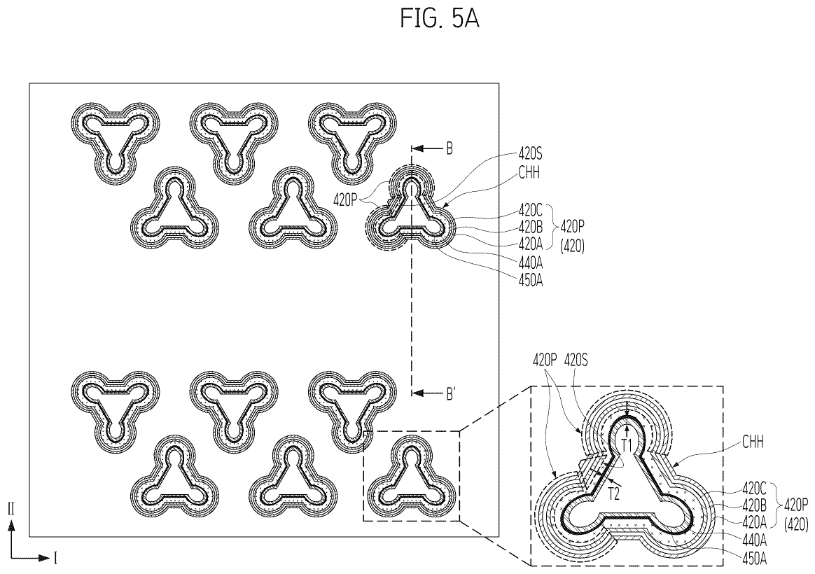

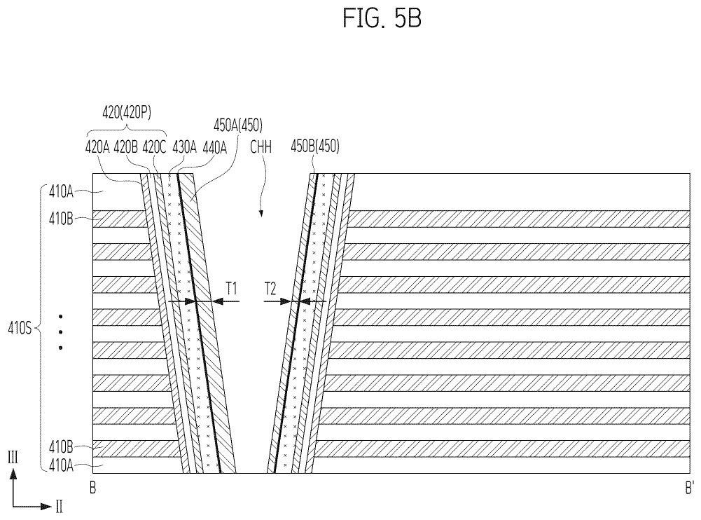

Referring to FIGS. 5A and 5B, a liner layer 440A may be formed on the channel layer 430A. For example, the liner layer 440A may be formed by oxidizing the channel layer 430A. The liner layer 440A may include an insulating material, such as oxide. The liner layer 440A may include silicon oxide. For example, the liner layer 440A may include SiO₂. However, the present disclosure is not limited thereto, and the liner layer 440A may be formed based on another process, such as deposition.

Subsequently, a first protective layer 450A may be formed on the liner layer 440A. For example, the first protective layer 450A including first portions 450A formed at locations corresponding to the second convex portions 430P of the channel layer 430A may be formed, and second portions 450B formed at locations corresponding to the second connection portions 430C of the channel layer 430A may be formed.

The first portions 450A may each have a first thickness T1. The second portions 450B may each have a second thickness T2 that is less than the first thickness T1. The first portions 450A may be formed at the locations corresponding to the second convex portions 430P having a bulbous shape protruding in different directions, and therefore, may be formed to be thicker than the second portions 450B formed at the locations corresponding to the second connection portions 430C that are flat. This is because a deposition speed in the second convex portions 430P that include a curved surface is higher than a deposition speed in the second connection portions 430C that are flat.

The first protective layer 450A may be formed based on a deposition method. In a process of forming the first protective layer 450A, a material included in the first protective layer 450A may diffuse into the channel layer 430A. In such a case, the liner layer 440A may prevent or reduce the diffusion of the material included in the first protective layer 450A into the channel layer 430A. The first protective layer 450A may include a different material compared to the liner layer 440A. For example, the first protective layer 450A may include an insulating material, such as nitride. The first protective layer 450A may include silicon nitride. For example, the first protective layer 450A may include Si₃N₄.

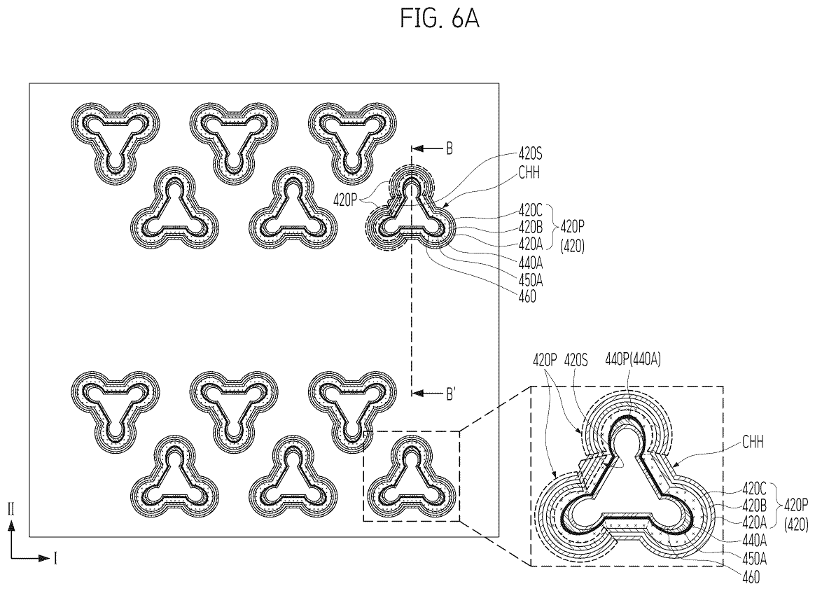

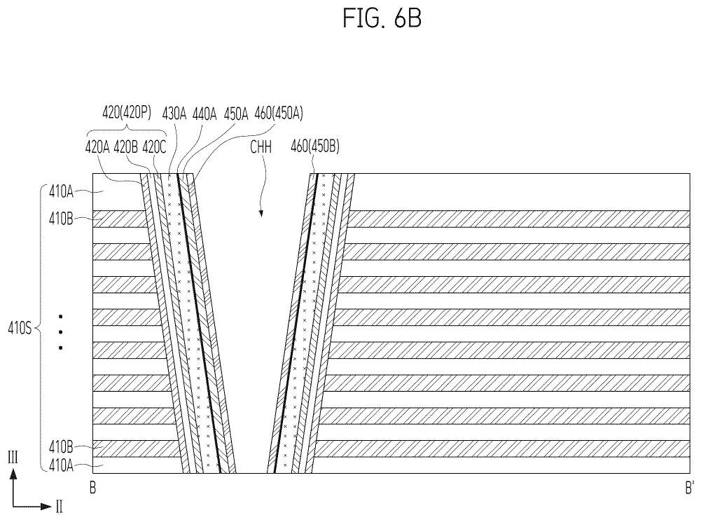

Referring to FIGS. 6A and 6B, a sacrificial layer 460 may be formed. For example, the sacrificial layer 460 may be formed by oxidizing the first portions 450A and the second portions 450B of the first protective layer 450A. The sacrificial layer 460 may include portions formed by only partially oxidizing the first portions 450A and portions formed by entirely oxidizing the second portions 450B. The difference in oxidation is that, because the second portions 450B is thinner than the first portion 450A, even though the second portions 450B are entirely oxidized, the first portions 450A might not be oxidized. In addition, the first portions 450A formed at the locations corresponding to the second convex portions 430P may have a greater surface energy than the second portions 450B formed at the locations corresponding to the second connection portions 430C in an oxidation process, and thus, a thickness at which the first portions 450A are oxidized may be less than a thickness at which the second portions 450B are oxidized. When the surface energy is great, there is a tendency to maintain a current structure, and thus, reactivity with an oxidizing gas or the like used during oxidation may be small. Accordingly, the second portions 450B may be entirely oxidized, and portions of the first portions 450A may remain without being oxidized. The sacrificial layer 460 may include an insulating material, such as oxide. The sacrificial layer 460 may include silicon oxide. For example, the sacrificial layer 460 may include SiO₂.

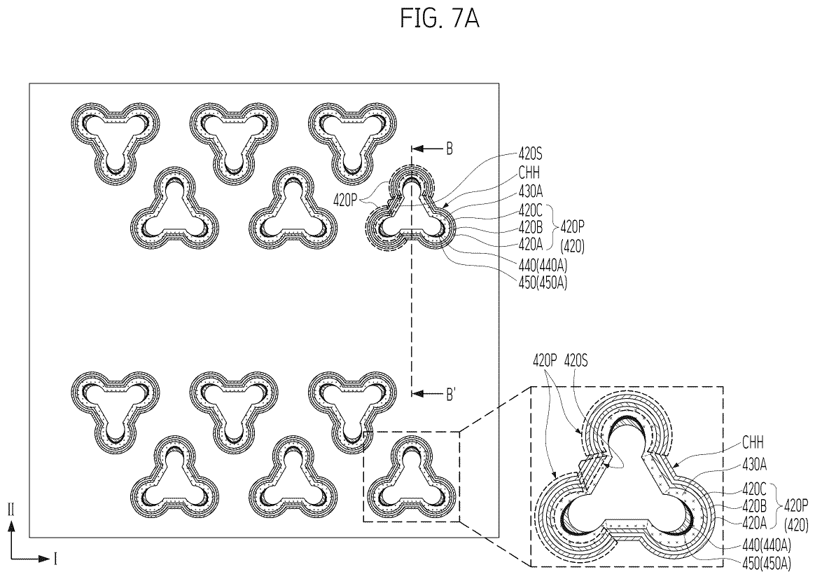

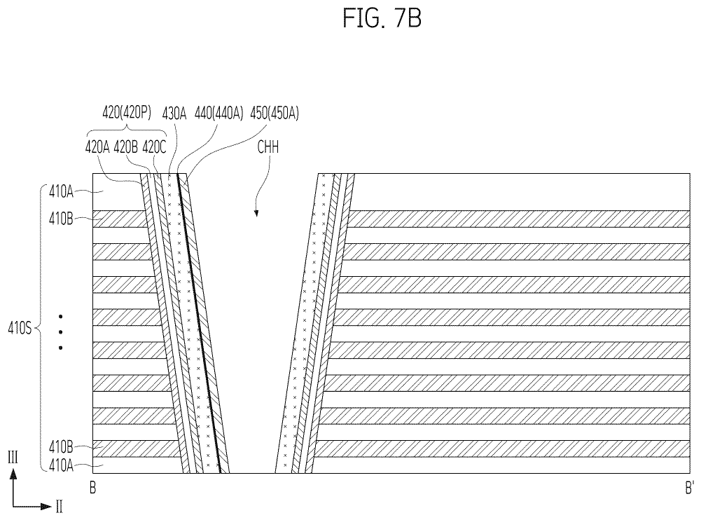

Referring to FIGS. 7A and 7B, first protective patterns 450 may be formed by removing the sacrificial layer 460. For example, the first protective patterns 450 may be formed by removing the oxidized portions of the first portions 450A and the second portions 450B of the first protective layer 450A. In other words, the first protective patterns 450 may be formed by removing the sacrificial layer 460. In such a case, the first protective patterns 450 may remain in regions corresponding to the second convex portions 430P. In this case, the first protective patterns 450 may each have a crescent shape.

In a process of removing the sacrificial layer 460, the liner layer 440A may be separated into liner patterns 440. Because the liner layer 440A and the sacrificial layer 460 may include substantially the same material, a portion of the liner layer 440A may be removed in the process of removing the sacrificial layer 460. Here, the liner patterns 440 may remain between the channel layer 430A and the first protective patterns 450. In other words, the liner patterns 440 may remain at the locations corresponding to the second convex portions 430P, respectively.

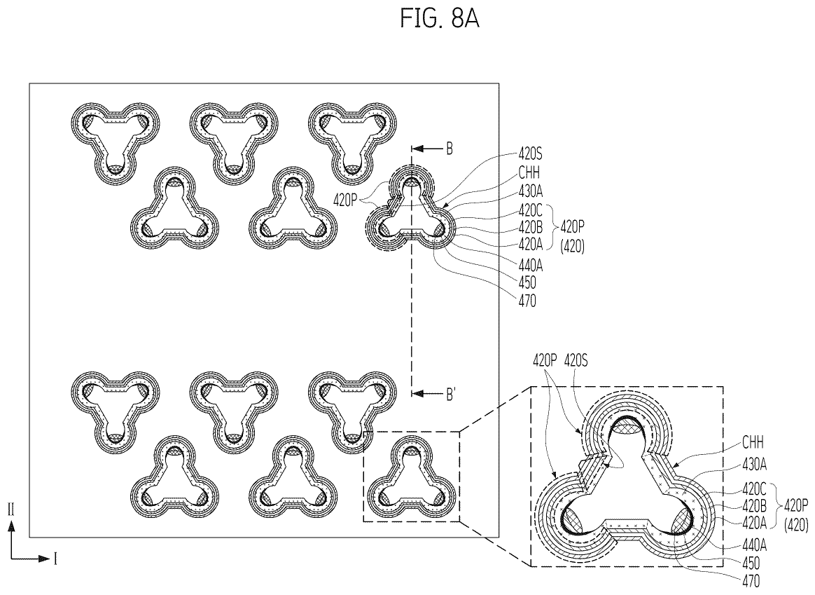

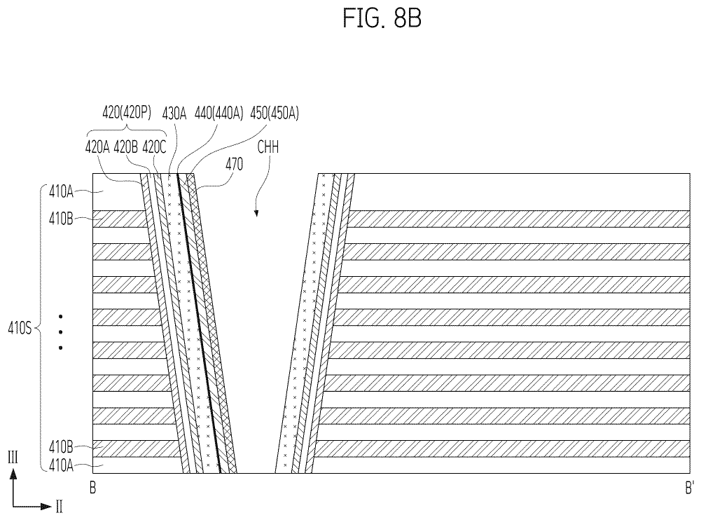

Referring to FIGS. 8A and 8B, second protective patterns 470 may be formed on the first protective patterns 450, respectively. For example, the second protective patterns 470 may be selectively deposited on the first protective patterns 450. In such a case, the second protective patterns 470 may each have a different shape compared to the liner patterns 440 and the first protective patterns 450. For example, the second protective patterns 470 may each have an elliptical shape. This is because the liner layer 440A and the first protective layer 450A are formed in-situ, whereas the second protective patterns 470 are formed based on a deposition method in a separate process.

Here, the second protective patterns 470 may each include a different material compared to the first protective patterns 450. For example, the second protective patterns 470 may each include an insulating material, such as oxide. The second protective patterns 470 may each include silicon oxide. As an example, the second protective patterns 470 may include SiO₂. As another example, the second protective patterns 470 may each include SiOC.

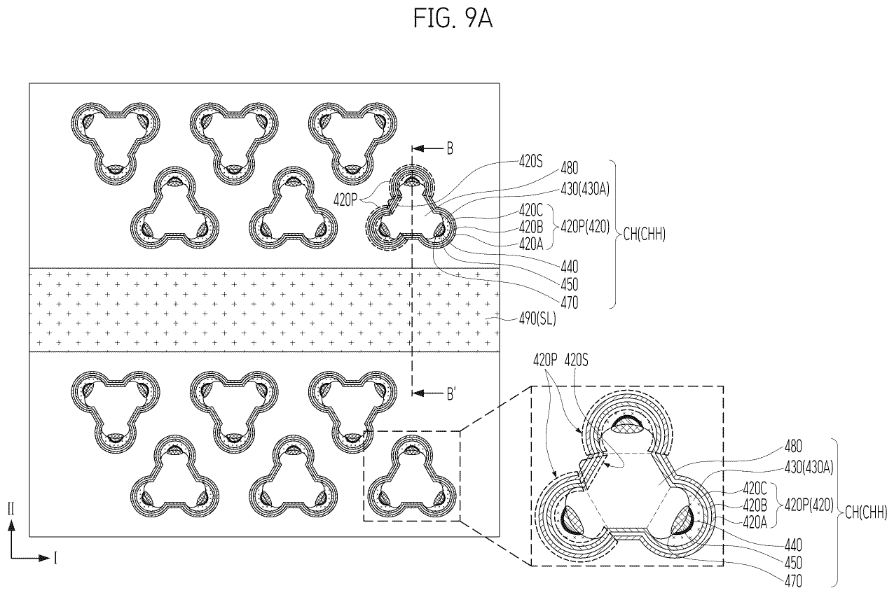

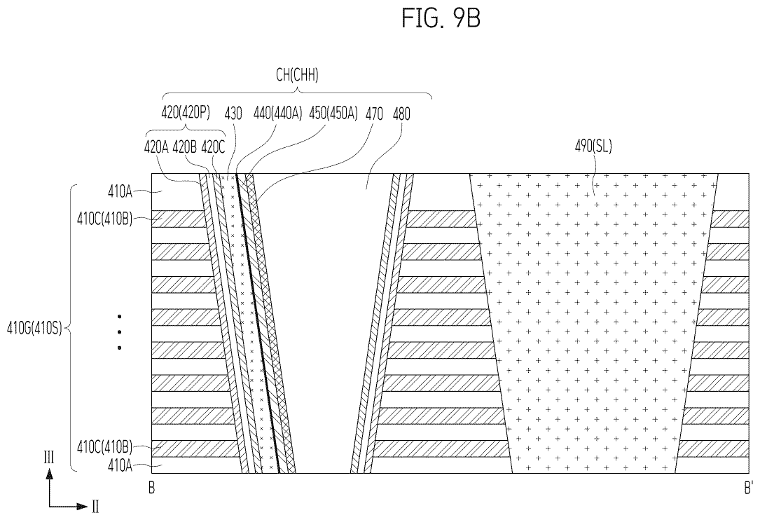

Referring to FIGS. 9A and 9B, channel patterns 430 may be formed by etching the channel layer 430A. For example, the channel patterns 430 may be formed by etching the second connection portions 430C of the channel layer 430A using the first protective patterns 450 and the second protective patterns 470 as etching barriers. In such a case, the channel layer 430A formed in regions corresponding to the first connection portions 420S of the memory layer 420 may be removed, and the channel layer 430A formed in regions corresponding to the first convex portions 420P of the memory layer 420 may remain and may be defined as the channel patterns 430.

When the channel patterns 430 are formed by etching the channel layer 430A, a wet process may be used. In addition, in the wet process, a mixed solution including a sulfuric acid, a phosphoric acid, a hydrofluoric acid, an acetic acid, and an organic material may be used. In addition, the liner patterns 440 and/or the second protective patterns 470 may be partially etched during an etching process. However, the first protective patterns 450 might not be etched. In other words, because the mixed solution used in the wet process may include materials having an etching selectivity with respect to the first protective patterns 450, the first protective patterns 450 might not be etched, and the liner patterns 440, the second protective patterns 470, and/or the channel layer 430A may be selectively etched.

When the protective patterns do not exist in a process of forming the channel patterns by etching the channel layer, the channel patterns formed at the locations corresponding to the first convex portions of the memory layer might not have a uniform shape. In other words, the channel layer formed at the locations corresponding to the first convex portions may also be removed in a process of removing the channel layer formed at the locations corresponding to the connection portions of the memory layer, and thus, the channel patterns might not have a uniform shape. In such a case, the reliability of the semiconductor device may be deteriorated.

According to an embodiment of the present disclosure, first protective patterns 450 may be formed on the channel layer 430A. In such a case, the first protective patterns 450 may prevent the channel layer 430A formed at the locations corresponding to the first convex portions 420P from being etched, and thus, the channel patterns 430 may have a uniform shape.

In addition, the second protective patterns 470 may be formed on the first protective patterns 450. In such a case, the second protective patterns 470 may prevent the first protective patterns 450 from being etched in a process of etching the channel layer 430A. Because the mixed solution used in the process of etching the channel layer 430A may have a higher etching selectivity with respect to the channel layer 430A than with respect to the second protective patterns 470, the second protective patterns 470 formed on the first protective patterns 450 may protect the first protective patterns 450 in the process of etching the channel layer 430A. In such a case, the second protective patterns 470 may allow the channel patterns 430, respectively formed at the locations corresponding to the first convex portions 420P, to have a uniform shape together with the first protective patterns 450.

Subsequently, insulating cores 480 may be formed in the channel holes CHH, respectively. For example, the insulating core 480 may be formed to fill the channel hole CHH. Consequently, a channel structure CH including the memory layer 420, the channel patterns 430, the liner patterns 440, the first protective patterns 450, and the second protective patterns 470 may be formed. The insulating core 480 may include an insulating material, such as oxide. The insulating core 480 may include silicon oxide. For example, the insulating core 480 may include SiO₂.

Subsequently, a slit SL extending through the stack 410S may be formed. Subsequently, a gate structure 410G may be formed by removing the second material layers 410B through the slit SL and then forming third material layers 410C. Here, the third material layers 410C may be gate lines.

For reference, when the second material layers 410B each include a conductive material, a process of replacing the second material layers 410B with the third material layers 410C may be omitted. In such a case, the stack 410S may be used as the gate structure 410G.

Subsequently, a slit structure 490 may be formed in the slit SL. The slit structure 490 may include at least one of an insulating material, a semiconductor material, or a conductive material.

According to the method described above, the channel hole CHH may have the clover shape, and the memory layer 420 may include the first convex portions 420P. The channel layer 430A may be formed along a profile of the memory layer 420, and may include the second convex portions 430P corresponding to the first convex portions 420P. In addition, the liner patterns 440, the first protective patterns 450, and the second protective patterns 470 may be formed at the locations corresponding to the second convex portions 430P. In such a case, in the process of forming channel patterns 430 by etching the channel layer 430A, the channel patterns 430 formed at the locations corresponding to the first convex portions 420P may have a uniform shape. Accordingly, the reliability of the semiconductor device may be improved.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including insulating layers and conductive layers that are alternately stacked;
a memory layer extending through the gate structure and including first convex portions protruding in different directions and first connection portions connecting the first convex portions to each other;
an insulating core located in the memory layer;
channel patterns located between the first convex portions and the insulating core, respectively;
first protective patterns located between the channel patterns and the insulating core, respectively; and
second protective patterns located between the first protective patterns and the insulating core, respectively.

2. The semiconductor device of claim 1, further comprising liner patterns located between the channel patterns and the first protective patterns, respectively.

3. The semiconductor device of claim 2, wherein the first protective patterns include outer walls in contact with the liner patterns and inner walls in contact with the second protective patterns.

4. The semiconductor device of claim 3, wherein a curvature of the outer walls of the first protective patterns is greater than a curvature of the inner walls of the first protective patterns.

5. The semiconductor device of claim 2, wherein the first protective patterns are thicker in a center region thereof than in an edge region thereof.

6. The semiconductor device of claim 2, wherein the liner patterns each include a different material compared to the first protective patterns.

7. The semiconductor device of claim 1, wherein the insulating core includes second convex portions corresponding to the first convex portions and a second connection portion corresponding to the first connection portions.

8. The semiconductor device of claim 1, wherein the first protective patterns each include a different material compared to the second protective patterns.

9. The semiconductor device of claim 1, wherein the gate structure includes a staircase structure, and
wherein the semiconductor device further comprises:
an interlayer insulating layer located on the staircase structure; and
a contact via extending through the interlayer insulating layer and connected to one of the conductive layers.

10. The semiconductor device of claim 1, wherein the gate structure includes a staircase structure, and
wherein the semiconductor device further comprises:
an interlayer insulating layer located on the staircase structure;
a contact via extending through the interlayer insulating layer and the staircase structure and connected to one of the conductive layers; and
contact spacers located at levels corresponding to the conductive layers.

11. The semiconductor device of claim 1, further comprising:
a contact via extending through the gate structure and connected to one of the conductive layers; and
a contact spacer surrounding a sidewall of the contact via.

12. A semiconductor device comprising:
a gate structure including insulating layers and conductive layers that are alternately stacked;
an insulating core extending through the gate structure and including second convex portions protruding in different directions and a second connection portion connecting the second convex portions to each other;
channel patterns located between the second convex portions and the gate structure, respectively;
liner patterns located between the second convex portions and the channel patterns, respectively;
first protective patterns located between the second convex portions and the liner patterns, respectively; and
second protective patterns located between the second convex portions and the first protective patterns, respectively.

13. The semiconductor device of claim 12, further comprising a memory layer surrounding the insulating core.

14. The semiconductor device of claim 13, wherein the memory layer includes first convex portions formed at locations corresponding to the second convex portions and first connection portions formed at locations corresponding to the second connection portion.

15. The semiconductor device of claim 12, wherein the first protective patterns include outer walls in contact with the liner patterns and inner walls in contact with the second protective patterns.

16. The semiconductor device of claim 15, wherein a curvature of the outer walls of the first protective patterns is greater than a curvature of the inner walls of the first protective patterns.

17. The semiconductor device of claim 12, wherein the first protective patterns are thicker in a center region thereof than in an edge region thereof.

18. The semiconductor device of claim 12, wherein the first protective patterns each include a different material compared to the second protective patterns.

19. The semiconductor device of claim 12, wherein the liner patterns each include a different material compared to the first protective patterns.

20. The semiconductor device of claim 12, wherein the gate structure includes a staircase structure, and
wherein the semiconductor device further comprises:
an interlayer insulating layer located on the staircase structure; and
a contact via extending through the interlayer insulating layer and connected to one of the conductive layers.

21. The semiconductor device of claim 12, wherein the gate structure includes a staircase structure, and
wherein the semiconductor device further comprises:
an interlayer insulating layer located on the staircase structure;
a contact via extending through the interlayer insulating layer and the staircase structure and connected to one of the conductive layers; and
contact spacers located at levels corresponding to the conductive layers.

22. The semiconductor device of claim 12, further comprising:
a contact via extending through the gate structure and connected to one of the conductive layers; and
a contact spacer surrounding a sidewall of the contact via.
